(19) United States
(12) Patent Application Publication
(10) Pub. No.: US 2004/0132287 A1
(43) Pub. Date: Jul. 8, 2004

(54) Dry etch process for copper

(75) Inventors: Lawrence S. Fischer, Poughkeepsie, NY (US); Steven Brett Herschbein, Hopewell Junction, NY (US); Chad Rue, Poughkeepsie, NY (US); Carmelo F. Scrudato, Ossining, NY (US); Michael Ray Sievers, Poughkeepsie, NY (US)

Correspondence Address: Steven Fischman, Esq., Scully, Scott, Murphy & Presser, 400 Garden City Plaza, Garden City, NY, 11530, US

(73) Assignee: INTERNATIONAL BUSINESS MACHINES CORPORATION, ARMONK, NY

(21) Appl. No.: 10/338,095

(22) Filed: Jan. 7, 2003

(51) Int. Cl. H01L 21/44; C23C 14/00

(52) U.S. Cl. 438/687; 204/192.1; 250/492.3

(57) ABSTRACT

A method of focused ion beam milling of a copper on a sample, and a focused ion beam apparatus. The method comprises the steps of exposing an area of copper on the sample; and forming a given feature in the copper area by using the focused ion beam to draw a mill box in the copper area, scanning the focused ion beam across the mill box for an extended period of time to remove a portion of the copper in the copper area and thereby to form the given feature, and introducing tetramethylcyclotetrasiloxane (TMCTS) in said area during the scanning step. After the copper feature is formed, a very light dose of XeF2 may be introduced to clean up any residue that may have formed.

### BACKGROUND OF THE INVENTION

1. Field of the Invention

This invention generally relates to etching integrated circuits, and more specifically, to a method and system for dry etching copper features in integrated circuits using a focused ion beam.

2. Background Art

Focused ion beam (FIB) systems are widely used in microscopic-scale manufacturing operations because of their ability to image, etch, mill, deposit, and analyze with great precision. Ion columns on FIB systems using gallium liquid metal ion sources (LMIS), for example, can provide five to seven nanometer lateral imaging resolution. Because of their versatility and precision, FIB systems have gained wide spread acceptance in the integrated circuit (IC) industry as analytical tools for use in process development, failure analysis, and defect characterization.

The ion beam of a FIB system typically scans the surface of the integrated circuit in a raster pattern. This raster pattern is often used first to produce an image of the surface showing the top lines and elements of the circuit. The image is used together with circuit layout information to navigate the ion beam around the integrated circuit to locate a specific element or a feature of the circuit. Upon moving the raster pattern to the local area of the feature of interest, the ion beam current is increased to cut into the die and to expose circuit features in buried layers. The FIB system can then alter the exposed circuit by cutting conductive traces to break electrical connections or by depositing conductive material to provide new electrical connections. A gaseous material is often directed to the sample at the impact point of the ion beam, and the ions induce a chemical reaction that selectively increases the etch rate or deposits material, depending on the gaseous compound that is used.

Until recently, milling applications for FIB systems on metal interconnects of integrated circuits have been limited to the sputtering of polycrystalline aluminum or tungsten. Both materials can be milled by rastering a beam of gallium ions across the area of interest. To increase the etch rate, a gas containing a member of the halogen group (bromine, chlorine, or iodine) is often directed to the impact point of the ion beam to enhance etching. The beam is typically scanned across the area to be milled using digital electronics that step the beam from point to point. The distance between points is referred to as the pixel spacing.

In recent years, semiconductor manufacturers have begun a migration toward the use of copper as a replacement for aluminum interconnects. As manufacturers strive to increase the speed at which chips work, the use of copper interconnects provides several advantages over aluminum. For instance, copper has lower sheet resistance and exhibits both improved metal line and line/via/line electromigration reliability.

The halogens that are used to enhance focused ion beam etching of other metal interconnect materials do not significantly enhance the etching of copper. For example, the etch byproducts formed during the use of halogen compounds on copper at room temperature have low volatility and tend to leave detrimental deposits on the sample surface and via side walls. Moreover, the milling of copper without chemicals has been found to produce non-uniform material removal, even when the ion beam is applied uniformly.

Procedures for etching copper are disclosed, for example, in U.S. Pat. No. 6,322,672 and U.S. patent application publication US2001/0053605 A1. These procedures are not completely satisfactory, however. In particular, the procedures disclosed in these references appear to be effective only in milling large (several micron) copper features, and do not appear to be efficient in milling smaller features. In addition, these procedures use a metal deposition gas in the process, and removing a metal with a metal leaves an undesirable conductive residue in the milled area.

### SUMMARY OF THE INVENTION

An object of this invention is to improve methods and systems for etching integrated circuits.

Another object of the present invention is to provide an even and complete dry etching of copper features in integrated circuits.

A further object of the invention is to provide a true dry etch process that clearly mils copper, in an integrated circuit, leaving no noticeable conductive residue behind.

These and other objectives are attained with a method of focused ion beam milling of a copper on a sample, and a focused ion beam apparatus. The method comprises the steps of exposing an area of copper on the sample; and forming a given feature in the copper area by using the focused ion beam to draw a mill box in the copper area, scanning the focused ion beam across the mill box for an extended period of time to remove a portion of the copper in the copper area and thereby to form the given feature, and introducing tetramethylcyclotetrasiloxane (TMCTS) in said area during the scanning step. After the copper feature is formed, a very light dose of XeF2 may be introduced to clean up any residue that may have formed.

Further benefits and advantages of the invention will become apparent from a consideration of the following detailed description, given with reference to the accompanying drawings, which specify and show preferred embodiments of the invention.

### BRIEF DESCRIPTION OF THE DRAWINGS

FIG. 1 schematically illustrates a focused ion beam system that may be used in the practice of this invention.

FIG. 2 is a flow chart showing a preferred method embodying the present invention.

FIG. 3 is a cross-sectional view of a semi-conductor device having a copper layer.

FIG. 4 shows the device of FIG. 3 after a copper feature has been opened-up.

FIG. 5 is a top view of the semiconductor device of FIG. 4.

FIG. 6 is a cross-sectional view of the device of FIG. 4 after the copper feature is cut with a TMCTS enhanced mill.

### DETAILED DESCRIPTION OF THE PREFERRED EMBODIMENTS

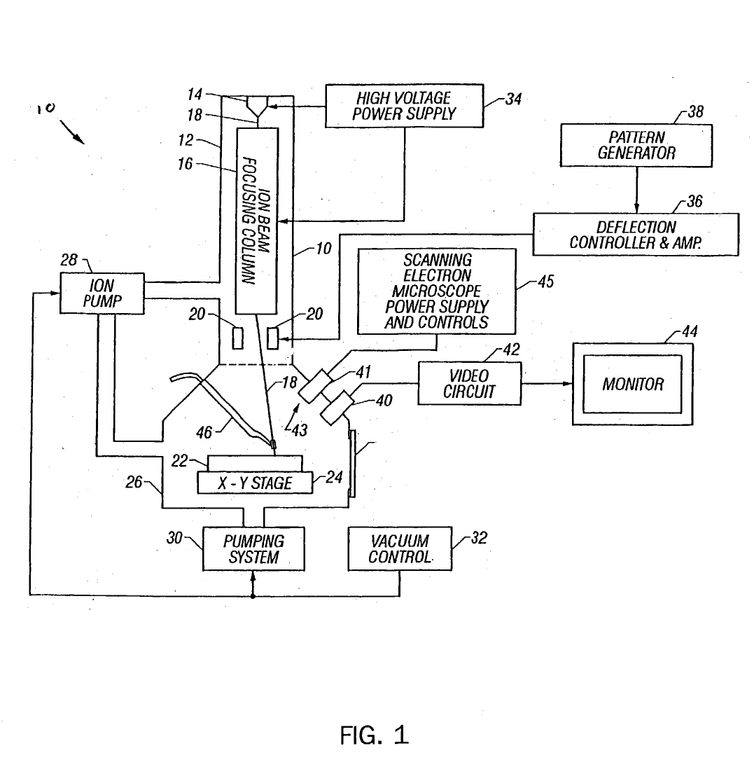

FIG. 1 illustrates a focused ion beam system 10 including an evacuated envelope 12 having an upper neck portion within which are located a liquid metal ion source 14 and a focusing column 16 including extractor electrodes and an electrostatic optical system. Ion beam 18 passes from source 14 through column 16 and between electrostatic deflection means schematically indicated at 20 toward sample 22, which comprises, for example, a semiconductor device positioned on movable X-Y stage 24 within lower chamber 26. An ion pump 28 is employed for evacuating neck portion 12.

The chamber 26 is evacuated with turbomolecular and mechanical pumping system 30 under the control of vacuum controller 32. The vacuum system provides within chamber 26 a vacuum of between approximately 1×10⁻⁷ Torr and 5×10⁻⁴ Torr. If an etch-assisting or an etch retarding gas is used, the chamber background pressure is typically about 1×10⁻⁵ Torr.

High voltage power supply 34 is connected to metal ion source 14 as well as to appropriate electrodes in focusing column 16 for forming an approximately 1 keV to 60 keV ion beam 18 and directing the same downwardly. Deflection controller and amplifier 36, operated in accordance with a prescribed pattern provided by pattern generator 38, is coupled to deflection plates 20 whereby beam 18 may be controlled to trace out a corresponding pattern on the upper surface of sample 22.

The ion source 14 typically provides a metal ion beam of gallium, although other ion sources, such as a multicusp or other plasma ion source, can be used. The source typically is capable of being focused into a sub one-tenth micron wide beam at sample 22 for either modifying the surface 22 by ion milling, enhanced etch, material deposition, or for the purpose of imaging the surface 22. A charged particle multiplier 40 used for detecting secondary ion or electron emission for imaging is connected to video circuit and amplifier 42, the latter supplying drive for video monitor 44, which also receives deflection signals from controller 36. A fluid delivery system 46 extends into lower chamber 26 for introducing and directing a gaseous vapor toward sample 22. A door 48 provides access to the interior of chamber 26, and this door is opened for inserting sample 22 on stage 24 which may be heated or cooled.

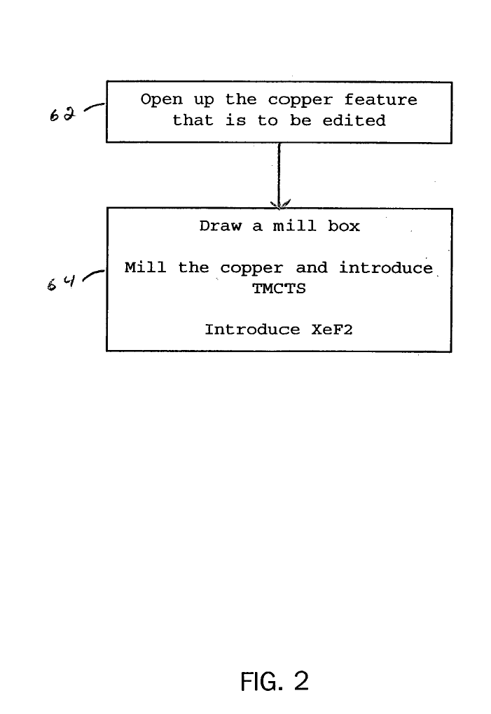

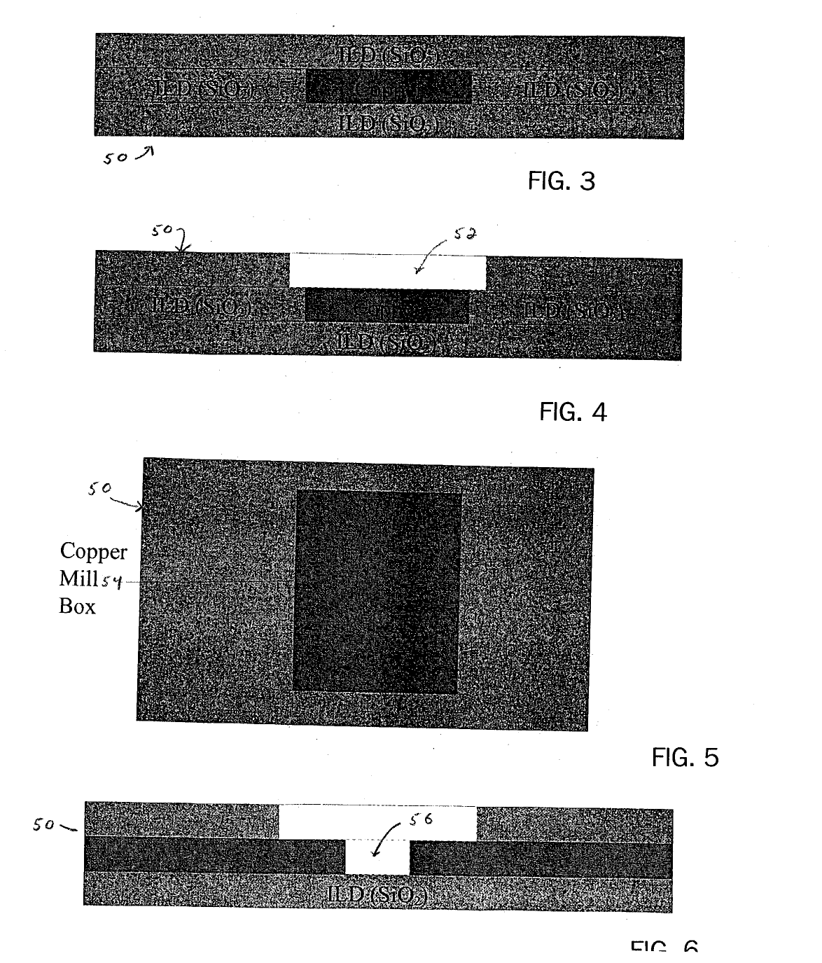

In a preferred embodiment of the present invention, signals applied to deflection controller and amplifier 36 cause the focused ion beam to move within a target area to produce a clean copper milling, leaving no noticeable conductive residue behind. FIG. 2 is a flow chart showing a preferred process of the present invention, and FIG. 3 shows, in greater detail, a semiconductor device 50 with which the present invention may be used.

With reference to FIGS. 2 and 3, a first step 62 in this dry etch process is to open up the copper feature that is to be edited, as shown at 52 in FIG. 4. Any suitable procedure may be used to do this, and chemistry for these processes are well established. With the copper feature 52 exposed, a mill box to cut the copper is drawn in, at step 64, and lined up to the feature, as shown at 54 in FIGS. 5 and 6. Established parameters for a gas assisted etch type of mill box may be used to do this, except that the dwell time is increased by roughly an order of magnitude. Such established procedures are disclosed, for example, in U.S. Pat. No. 6,322,672.

Now, the two chemicals that will assist in the milling of the copper are introduced. The milling can be done in one of two ways. With one procedure, the milling of the copper line is started, and tetramethylcyclotetrasiloxane (TMCTS) is introduced with a BT setting that is low (approximately 0.5 Torr). When the copper line is seen to disappear, as illustrated at 56 in FIG. 6, standard (<0.1) XeF2 mill with a very light dose (<0.1) is introduced to clean up any residue that may have formed.

The preferred embodiment of the invention, as described above in detail, has a number of advantages. In particular, the invention cleanly removes the copper with no noticeable copper residue left behind. Also, the process has no grain dependence. Moreover, the process of this invention can easily be incorporated into any FIB instrument that has silicone deposition capabilities.

While it is apparent that the invention herein disclosed is well calculated to fulfill the objects stated above, it will be appreciated that numerous modifications and embodiments may be devised by those skilled in the art, and it is intended that the appended claims cover all such modifications and embodiments as fall within the true spirit and scope of the present invention.

1. A method of focused ion beam milling of a copper on a sample, comprising the steps of:
exposing an area of copper on the sample; and
forming a given feature in the copper area, including the steps of
i) using the focused ion beam to draw a mill box in said copper area,
i) scanning the focused ion beam across the mill box for a period of between 1 and 100 seconds to remove a portion of the copper in the copper area, and thereby to form the given feature, and
ii) introducing TMCTS in said area during the scanning step.

2. A method according to claim 1, wherein the scanning step includes the step of scanning the focused ion beam across the mill box for a period of between 10 and 50 seconds.

3. A method according to claim 1, wherein the scanning step includes the step of scanning the focused ion beam across the mill box for a period of between 20 and 25 seconds.

4. A method according to claim 1, wherein the step of introducing TMCTS in said area includes the step of introducing TMCTS into said area at less than 5.0 Torr.

5. A method according to claim 1, wherein the step of introducing TMCTS in said area includes the step of introducing TMCTS into said area at less than 1.0 Torr.

6. A method according to claim 1, wherein the step of introducing TMCTS in said area includes the step of introducing TMCTS into said area at approximately 0.5 Torr.

7. A method according to claim 1, wherein the forming step includes the step of (iv) introducing a dose of XeF2 into said area, after the given feature is formed, to remove any copper residue.

8. A method according to claim 7, wherein the step of introducing a dose of XeF2 into said area includes the step of introducing XeF2 into said area with a dose <1.0.

9. A method according to claim 8, wherein the step of introducing a dose of XeF2 into said area includes the step of introducing XeF2 into said area with a dose <0.1.

10. A focused ion beam apparatus, comprising:
an ion source for generating an ion beam;
an ion column including deflector electrodes for directing the ion beam onto a specified copper area of a sample;
a control programmed to operate the deflector electrodes to move the ion beam to draw a mill box on said area, and programmed to scan the ion beam across the mill box for a period of between 1 and 100 seconds to remove a portion of the copper in said copper area and thereby to form a given feature in the copper area; and
a gas nozzle to direct TMCTS in said area while the ion beam is being scanned across said area.

11. A focused ion beam apparatus according to claim 10, wherein the control is programmed to scan the ion beam across the mill box for a period of between 10 and 50 seconds.

12. A focused ion beam apparatus according to claim 10, wherein the control is programmed to scan the ion beam across the mill box for a period of between 20 and 25 seconds.

13. A focused ion beam apparatus according to claim 10, wherein TMCTS is introduced into said area, while the ion beam is being scanned across said area, at less than 5.0 Torr.

14. A focused ion beam apparatus according to claim 10, wherein TMCTS is introduced into said area, while the ion beam is being scanned across said area, at less than 1.0 Torr.

15. A focused ion beam apparatus according to claim 10, wherein TMCTS is introduced into said area, while the ion beam is being scanned across said area, at approximately 0.5 Torr.

16. A focused ion beam apparatus according to claim 10, wherein the gas nozzle includes means to introduce XeF2 into said area, after the given feature is formed, to remove any copper residue.

17. A focused ion beam apparatus according to claim 16, wherein the XeF2 is introduced into said area, after the given feature is formed, with a dose <0.1.
